(19) United States
(12) Patent Application Publication
(10) Pub. No.: US 2020/0091053 A1
(43) Pub. Date: Mar. 19, 2020

(54) INTEGRATED CIRCUIT PACKAGE SUPPORTS HAVING INDUCTORS WITH MAGNETIC MATERIAL

(71) Applicant: Intel Corporation, Santa Clara, CA (US)

(72) Inventors: Sameer Paital, Chandler, AZ (US); Srinivas V. Pietambaram, Chandler, AZ (US); Yonggang Li, Chandler, AZ (US); Kristof Kuwawi Darmawikarta, Chandler, AZ (US); Gang Duan, Chandler, AZ (US); Krishna Bharath, Phoenix, AZ (US); Michael James Hill, Gilbert, AZ (US)

(73) Assignee: Intel Corporation, Santa Clara, CA (US)

(21) Appl. No.: 16/131,511

(22) Filed: Sep. 14, 2018

(51) Int. Cl. H01L 23/498; H01F 27/28; H01F 27/24; H01F 27/02; H05K 1/18

(52) U.S. Cl. CPC H01L 23/49822; H01L 23/49838; H01F 27/28; H05K 2201/10378; H01F 27/022; H05K 1/181; H01F 27/24

(57) ABSTRACT

Disclosed herein are integrated circuit (IC) package supports having inductors with magnetic material therein. For example, in some embodiments, an IC package support may include an inductor including a solenoid, a first portion of a magnetic material in an interior of the solenoid, and a second portion of magnetic material outside the interior of the solenoid.

### BACKGROUND

Some integrated circuit (IC) packages may include an inductor (e.g., for use in integrated voltage regulators or radio frequency communication circuitry). Inductors having adequate electrical performance are typically large, taking up valuable volume in an IC package.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1A-1C are various views of a portion of an example integrated circuit (IC) package support including an inductor, in accordance with various embodiments.

FIGS. 2A-2C are various views of a portion of an example IC package support including an inductor, in accordance with various embodiments.

FIGS. 3A-3C are various views of a portion of an example IC package support including an inductor, in accordance with various embodiments.

FIGS. 4A-4C are various views of a portion of an example IC package support including an inductor, in accordance with various embodiments.

FIG. 5 is a side, cross-sectional view of a portion of an example IC package support including an inductor, in accordance with various embodiments.

FIGS. 6A-6B are various views of a portion of an example IC package support including an inductor, in accordance with various embodiments.

FIG. 7 is a side, cross-sectional view of a portion of an example IC package support including an inductor, in accordance with various embodiments.

FIGS. 8A-8O illustrate stages in another example process of manufacturing a vertical inductor, in accordance with various embodiments.

FIG. 9 is a top view of a wafer and dies that may be included in an IC package having an inductor in an IC package support, in accordance with any of the embodiments disclosed herein.

FIG. 10 is a side, cross-sectional view of an IC device that may be included in an IC package having an inductor in an IC package support, in accordance with any of the embodiments disclosed herein.

FIG. 11 is a side, cross-sectional view of an IC package that may include an inductor in an IC package support, in accordance with any of the embodiments disclosed herein.

FIG. 12 is a side, cross-sectional view of an IC device assembly that may include an IC package support, in accordance with any of the embodiments disclosed herein.

FIG. 13 is a block diagram of an example electrical device that may include an IC package support, in accordance with any of the embodiments disclosed herein.

### DETAILED DESCRIPTION

Disclosed herein are integrated circuit (IC) package supports having inductors with magnetic material therein. For example, in some embodiments, an IC package support may include an inductor including a solenoid, a first portion of a magnetic material in an interior of the solenoid, and a second portion of magnetic material outside the interior of the solenoid.

The miniaturization of computing and communication devices is conventionally limited by constraints on achievable size, power consumption, noise levels, and high frequency operation. In particular, conventional approaches to reducing the size of an inductor have not been able to achieve a manufacturable inductor with adequate performance characteristics. Conventional embedded spiral or meander-type coplanar air core inductors, for example, have typically suffered from lower Q values and achievable inductance due to the lower magnetic permeability associated with air or vacuum, a large lateral (e.g., x-y) footprint, and undesirable electromagnetic interference (EMI) arising from alternating magnetic flux. Inductors included in cored IC packages may utilize high permeability magnetic materials as the core for the package substrate and thereby improve performance, but such opportunities do not exist in coreless IC packages (which may be desired due to, e.g., reduced z-height relative to cored IC packages).

The IC package supports and inductors disclosed herein may exhibit improved performance with a smaller form factor relative to conventional approaches. The embodiments disclosed herein may effectively utilize the z-space of the IC package support without requiring additional space in the x- or y-direction, thereby mitigating EMI. In some embodiments, the inductors and manufacturing techniques disclosed herein may be utilized to form embedded inductors in coreless package supports, a result not previously achievable with adequate performance and manufacturability. The techniques disclosed herein may provide a relatively inexpensive manufacturing approach to three-dimensional integration of solenoid-type inductors as embedded passive devices in organic IC package supports (e.g., organic package substrates). The inductors disclosed herein may be utilized as integrated voltage regulators (IVRs) and/or in power storage devices, for example, and may exhibit improved inductance and Q values than conventional inductors. The IC package supports and inductors disclosed herein may be utilized in any appropriate setting; for example, the IC package supports and inductors disclosed herein may be advantageously utilized in reduced form factor settings, such as mobile applications, wearable devices, Internet of Things (loT), etc.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The drawings are not necessarily to scale. Although many of the drawings illustrate rectilinear structures with flat walls and right-angle corners, this is simply for ease of illustration, and actual devices made using these techniques will exhibit rounded corners, surface roughness, and other features.

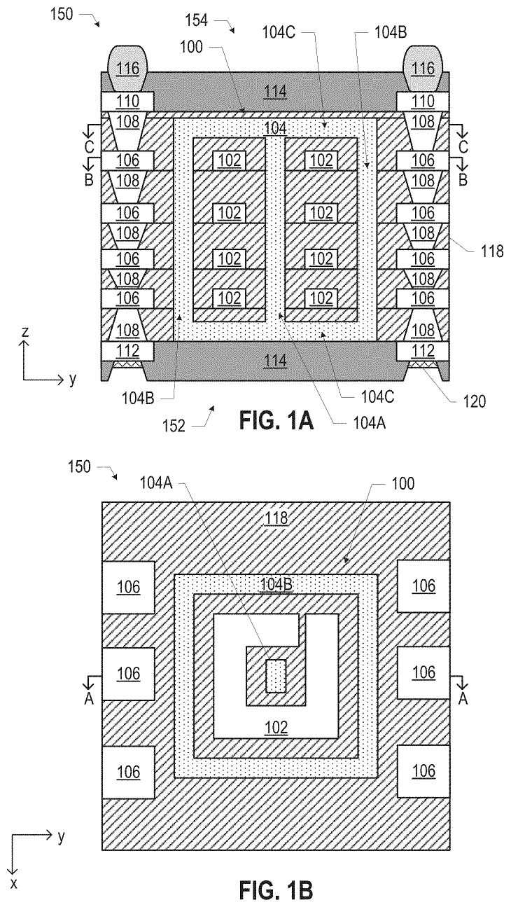

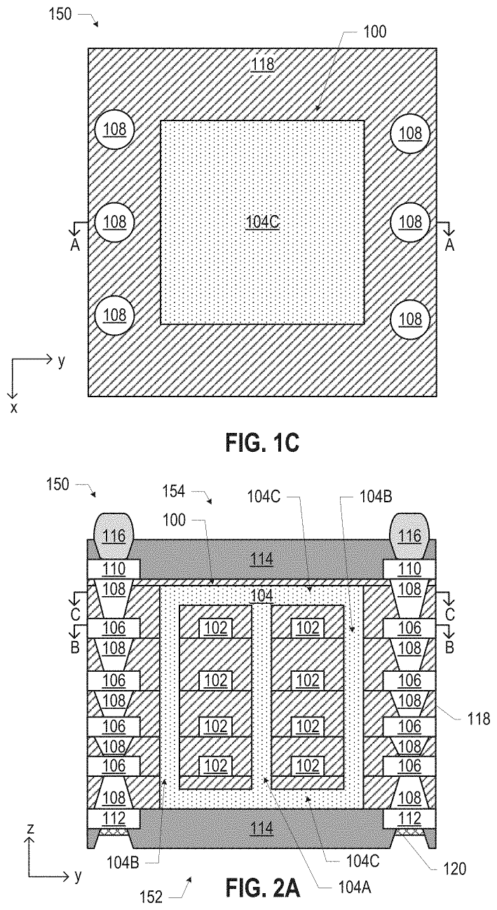

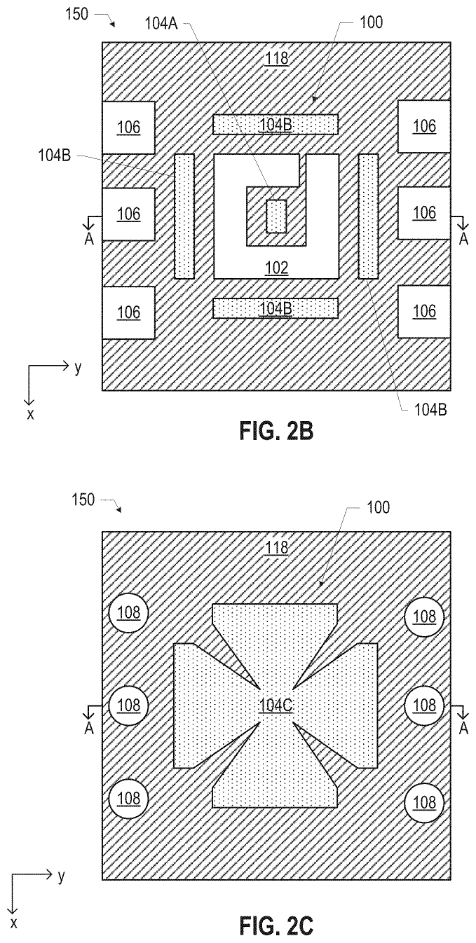

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, a “package” and an “IC package” are synonymous. When used to describe a range of dimensions, the phrase “between X and Y” represents a range that includes X and Y. For convenience, the phrase “FIG. 1” may be used to refer to the collection of drawings of FIGS. 1A-1C, the phrase “FIG. 2” may be used to refer to the collection of drawings of FIGS. 2A-2C, etc. As used herein, an “IC package support” or “package support” may refer to a structure included in an IC package that provides mechanical and/or electrical support to one or more dies or other electrical components (e.g., passive or active components) included in the IC package. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket). As used herein, a “cylinder” may refer to a hollow geometric figure having sides (subsets of which may or may not be parallel) and any suitable cross-section (e.g., circular, triangular, rectangular, hexagonal, etc.).

FIG. 1 presents various views of a portion of an example IC package support 150 including an inductor 100. In particular, FIG. 1A is a side, cross-sectional view through the section A-A of FIGS. 1B and 1C, FIG. 1B is a top, cross-sectional view through the section B-B of FIG. 1A, and FIG. 1C is a top, cross-sectional view through the section C-C of FIG. 1A. Although a single inductor 100 is illustrated in various ones of the drawings of the IC package supports 150 disclosed herein, this is simply for ease of illustration, and any of the IC package supports 150 disclosed herein may include any desired number and arrangement of inductors 100 (which may themselves take the form of any of the embodiments of the inductors 100 disclosed herein). In some embodiments, the IC package support 150 may be a package substrate (e.g., the package substrate 1652 discussed below with reference to FIG. 11) or an interposer (e.g., the interposer 1657 discussed below with reference to FIG. 11). A number of elements of FIG. 1 are shared with FIGS. 2-7; for ease of discussion, a description of these elements is not repeated, and these elements may take the form of any of the embodiments disclosed herein.

The IC package support 150 of FIG. 1 may include a first face 152 and an opposing second face 154. Conductive contacts 112 may be exposed at the first face 152 between regions of solder resist material 114. The conductive contacts 112 may have a surface finish material 120 thereon (e.g., including silver and/or gold); this surface finish material 120 may mitigate oxidation of the conductive contacts 112 and improve adhesion between the conductive contacts 112 and a solder (not shown) used to attach an electronic component (e.g., a die) to the conductive contacts 112. In some embodiments, the solder that couples to the conductive contacts 112 may provide first-level interconnects between the IC package support 150 and a die or other component (not shown). Solder balls 116 (e.g., micro balls) may be coupled to conductive contacts 110 at the second face 154 between regions of solder resist material 114. In some embodiments, the solder balls 116 may provide second-level interconnects between the IC package support 150 and a circuit board or another IC package (not shown, but discussed below with reference to FIG. 11).

The IC package support 150 may include multiple layers of dielectric material 118 between the faces 152 and 154. The dielectric material 118 may include a ceramic, a dielectric buildup film, an epoxy film having filler particles therein, or another suitable low-k material. The dielectric material 118 may be an organic material. Conductive structures, including conductive lines/pads 106 and conductive vias 108 may be arranged through the dielectric material 118 to provide conductive pathways between the first face 152 and the second face 154, between different locations at the first face 152, between different locations at the second face 154, or between the inductor 100 and either of the faces 152/154 (or other components embedded in the IC package supports 150, not shown). The particular arrangement of conductive lines/pads 106 and conductive vias 108 depicted in FIG. 1 (and others of the accompanying figures) is simply illustrative, and an IC package support 150 may include any suitable arrangement. In some embodiments, the thickness of a layer of the dielectric material 118 (in the z-direction) may be between 30 microns and 40 microns. In some embodiments, the thickness of a conductive line/pad 106 (in the z-direction) may be between 10 microns and 15 microns. In some embodiments, the height of a conductive via 108 (in the z-direction) may be between 20 microns and 25 microns. In some embodiments, the thickness of the IC package support 150 (in the z-direction) may be less than 500 microns.

The IC package support 150 may include an inductor 100 that extends through multiples ones of the layers of dielectric material 118. The inductor 100 may include a solenoid 102 and magnetic material 104. The solenoid 102 may be formed of conductive lines and vias arranged to form a spiral-type shape through the dielectric material 118; the vias of the solenoid 102 may be formed with a high aspect ratio (e.g., a height-to-width ratio greater than or equal to 2:1), which may reduce the stray capacitance and increase the inductance of the inductor 100. The solenoid 102 may have a longitudinal axis through the volume in the interior of the solenoid 102 that is oriented in the z-direction, perpendicular to the first face 152 and to the second face 154. Any suitable material may be used in the solenoid 102 (and the conductive lines/pads 106 and conductive vias 108) disclosed herein, such as a metal (e.g., copper).

The magnetic material 104 of the inductor 100 may include a portion 104A in the interior of the solenoid 102 and a portion 104B exterior to the solenoid 102. As illustrated in FIG. 1B, the portion 104A of the magnetic material 104 may take the form of a column, and the portion 104B of the magnetic material may take the form of a cylinder. The portion 104B of FIG. 1 may have a rectangular cross-section (e.g., as illustrated in FIG. 1B), but a cylindrical portion 104B may have any suitable cross-section. The portion 104B may laterally surround the solenoid 102, and may have substantially solid walls. In other embodiments, the walls of the portion 104B may not be solid, but may instead be formed of multiple columns of magnetic material 104 spaced apart from each other (not shown).

The magnetic material 104 may also include portions 104C that are exterior to the solenoid 102 and arranged “above” and “below” the solenoid 102 in the z-direction. That is, the portions 104C are located between the solenoid 102 and the faces 152/154. In the embodiment of FIG. 1, the portions 104C may be in contact with the portions 104A and 104B, providing a closed magnetic material loop in and around the solenoid 102. As shown in FIG. 1C, the portions 104C may have a rectangular cross-section (e.g., to match the rectangular cross-section of the portion 104B), but in other embodiments, the portion 104C may have any suitable cross-section. The portion 104C illustrated in FIG. 1 may be substantially solid, but in other embodiments, the portion 104C may be provided by multiple lines of magnetic material spaced apart from each other (not shown) or any other desired arrangement.

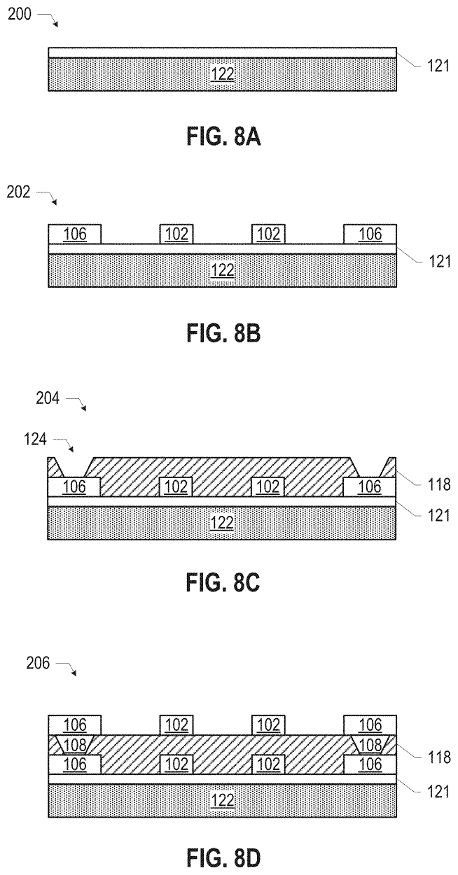

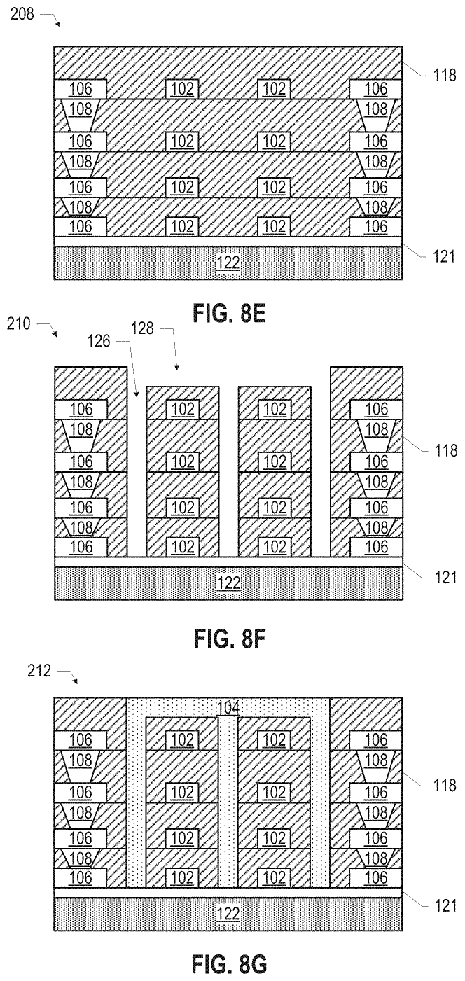

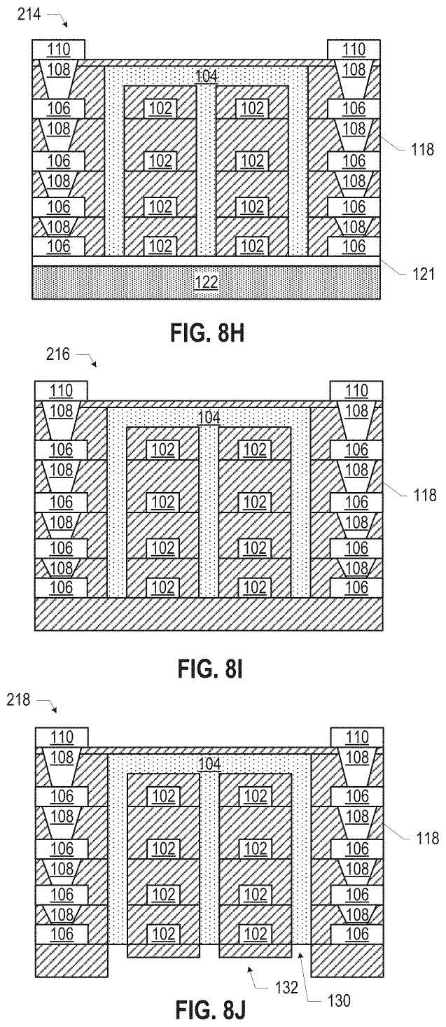

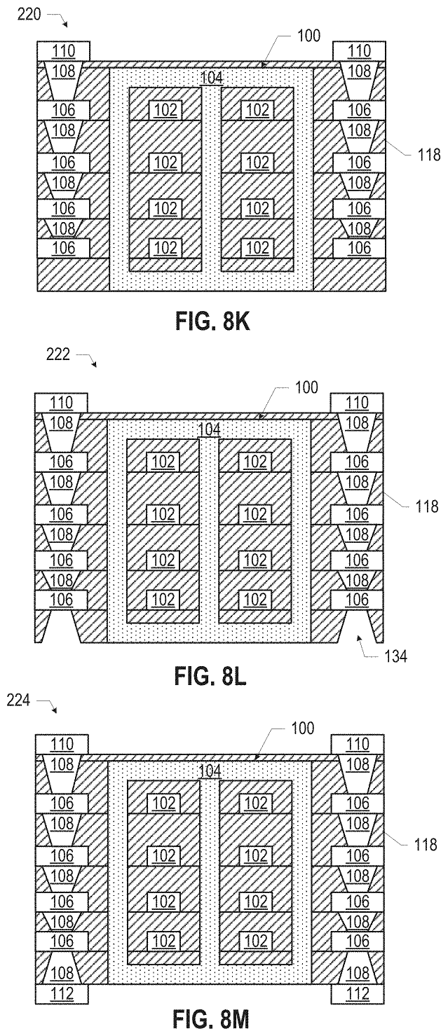

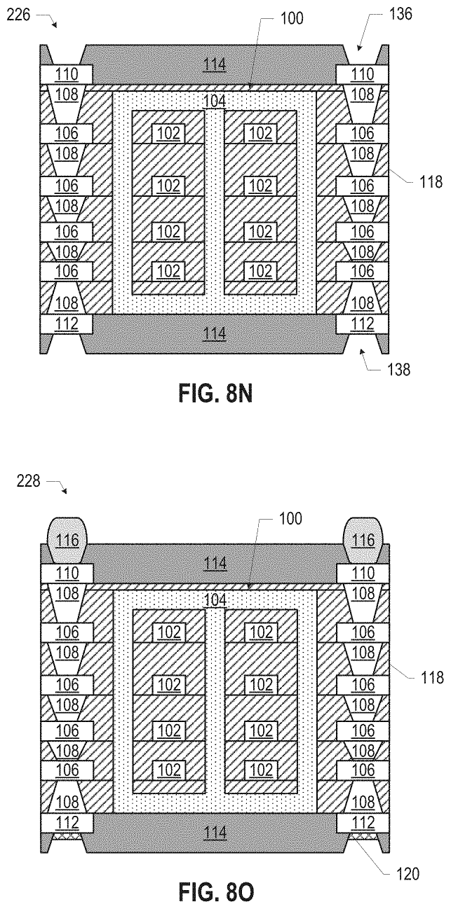

The magnetic material 104 may have any suitable composition. For example, the magnetic material 104 may include cobalt, iron, or nickel. In some embodiments, the magnetic material 104 may include iron and cobalt (e.g., in the form of an iron-cobalt-based ferromagnetic alloy powder). In some embodiments, the magnetic material 104 may include iron and nickel (e.g., in the form of an iron-nickel-based ferromagnetic alloy powder). In some embodiments, the magnetic material 104 may include flakes of a magnetic material (e.g., flakes of cobalt iron oxide, cobalt-nickel-iron alloys, nickel-iron-molybdenum alloys, and/or nickel-iron alloys). Such alloys may have a narrow hysteresis loop with low coercive magnetic field, which may have low hysteresis loss and thus may be desirable for inductor applications. The magnetic material 104 may also include carrier polymers (e.g., epoxy resins or polyimides) and an organic solvent; when applied (e.g., as discussed below with reference to FIG. 8), the magnetic material 104 may be a slurry that may be cured during manufacturing. For example, iron-cobalt and iron-nickel alloys may have a relative permeability greater than 1000 at low frequencies (e.g., DC operation), and when composited with bonding materials (such as the carrier polymers and solvents discussed above) to allow for high frequency operation (e.g., greater than 100 megahertz), the magnetic material 104 may exhibit a relative permeability on the order of 10.

FIG. 2 illustrates an example IC package support 150 having many elements in common with the IC package support 150 of FIG. 1, but having a different arrangement of magnetic material 104 around the solenoid 102. Like FIG. 1, FIG. 2A is a side, cross-sectional view through the section A-A of FIGS. 2B and 2C, FIG. 2B is a top, cross-sectional view through the section B-B of FIG. 2A, and FIG. 2C is a top, cross-sectional view through the section C-C of FIG. 2A. In the embodiment of FIG. 2, the magnetic material 104 of the inductor 100 includes one portion 104A in the interior of the solenoid 102, and four portions 104B exterior to the solenoid. Like the portion 104A of FIG. 1, the portion 104A of the magnetic material 104 of FIG. 2 may take the form of a column. However, the portions 104B may be substantially planar walls that are separate from each other. These portions 104B may be solid walls, or may not be solid (e.g., formed of multiple columns of magnetic material 104 spaced apart from each other, not shown). The magnetic material 104 of FIG. 2 may also include portions 104C that are exterior to the solenoid 102 in the z-direction, as discussed above with reference to the portions 104C of FIG. 1. In the embodiment of FIG. 2, the portions 104C may be in contact with the portions 104A and 104B, providing a closed magnetic material loop in and around the solenoid 102. As shown in FIG. 10, the portions 104C may have a windmill-shaped cross-section (e.g., to couple the portion 104A with the portions 104B), but in other embodiments, the portions 104C may have any suitable cross-section (e.g., rectangular). The portion 104C illustrated in FIG. 2 may be substantially solid, but in other embodiments, the portion 104C may have any other suitable shape. Although four portions 104B are shown in FIG. 2, similar structures may be used with fewer than four portions 104B (e.g., two or three portions 104B) or more than four portions 104B.

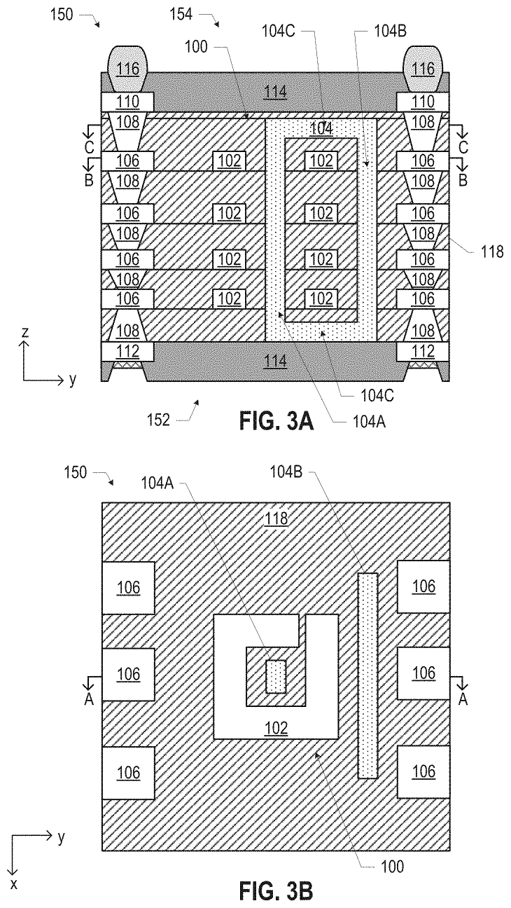

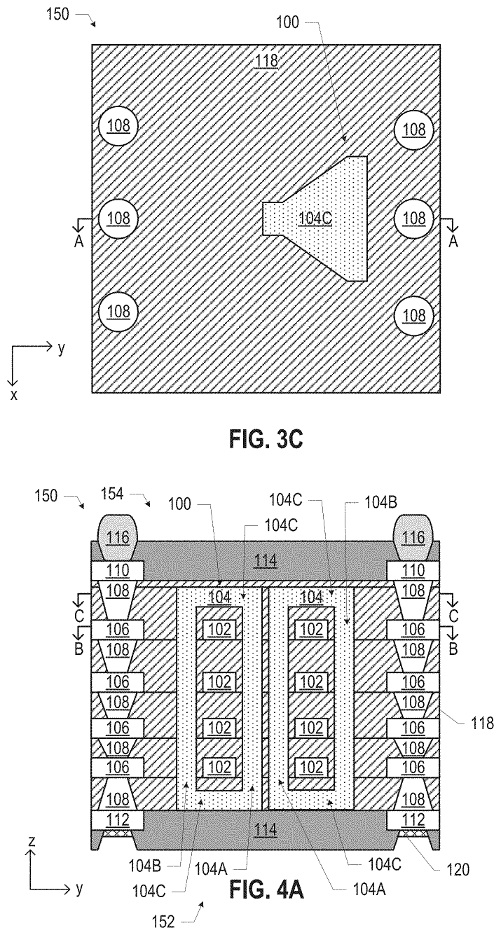

FIG. 3 illustrates an example IC package support 150 having many elements in common with the IC package supports 150 of FIGS. 1-2, but having a different arrangement of magnetic material 104 around the solenoid 102. Like FIG. 1, FIG. 3A is a side, cross-sectional view through the section A-A of FIGS. 3B and 3C, FIG. 3B is a top, cross-sectional view through the section B-B of FIG. 3A, and FIG. 3C is a top, cross-sectional view through the section C-C of FIG. 3A. In the embodiment of FIG. 3, the magnetic material 104 of the inductor 100 includes a portion 104A in the interior of the solenoid 102, and a portion 104B exterior to the solenoid. As illustrated in FIG. 3B, the portion 104A of the magnetic material 104 may take the form of a column, and the portion 104B of the magnetic material may be a substantially planar wall. This portion 104B may be a solid wall, or may not be solid (e.g., formed of multiple columns of magnetic material 104 spaced apart from each other, not shown). The magnetic material 104 of FIG. 3 may also include portions 104C that are exterior to the solenoid 102 in the z-direction, as discussed above with reference to the portions 104C of FIG. 1. In the embodiment of FIG. 3, the portions 104C may be in contact with the portions 104A and 104B, providing a closed magnetic material loop in and around the solenoid 102. As shown in FIG. 10, the portions 104C may have a speaker-shaped cross-section (e.g., to couple the portion 104A with the portion 104B), but in other embodiments, the portions 104C may have any suitable cross-section (e.g., rectangular). The portion 104C illustrated in FIG. 3 may be substantially solid, but in other embodiments, the portion 104C may have any other suitable shape. Although a single portion 104B is shown in FIG. 3, similar structures may be used with more than one portion 104B to form multiple distinct magnetic material loops in and around the solenoid 102 (e.g., two, three, or four loops).

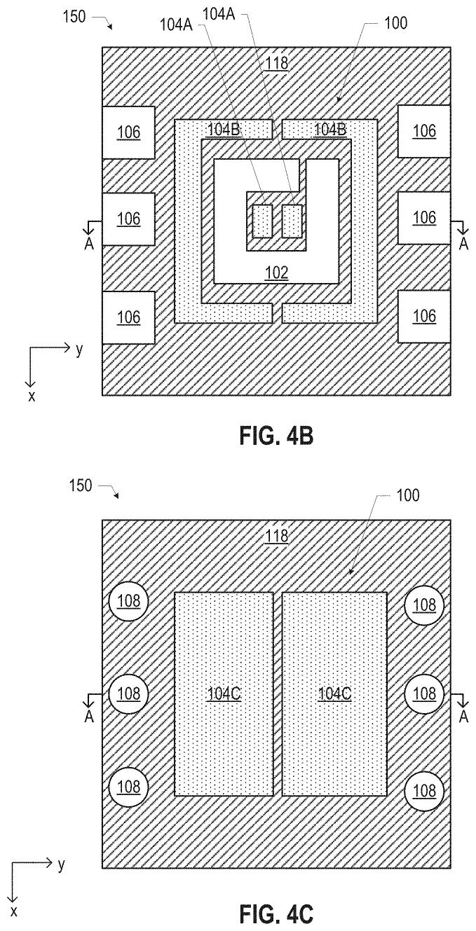

FIG. 4 illustrates an example IC package support 150 having many elements in common with the IC package supports 150 of FIGS. 1-3, but having a different arrangement of magnetic material 104 around the solenoid 102. Like FIG. 1, FIG. 4A is a side, cross-sectional view through the section A-A of FIGS. 4B and 4C, FIG. 4B is a top, cross-sectional view through the section B-B of FIG. 4A, and FIG. 4C is a top, cross-sectional view through the section C-C of FIG. 4A. In the embodiment of FIG. 4, the magnetic material 104 of the inductor 100 includes two portions 104A in the interior of the solenoid 102, and two portions 104B exterior to the solenoid. As illustrated in FIG. 4B, the portions 104A of the magnetic material 104 may take the form of columns, and the portions 104B of the magnetic material may have C-shaped cross-sections. As noted above with reference to FIG. 1, the portions 104B may have substantially solid walls, or may not be solid (e.g., formed of multiple columns of magnetic material 104 spaced apart from each other, not shown). The magnetic material 104 of FIG. 4 may also include portions 104C that are exterior to the solenoid 102 in the z-direction, as discussed above with reference to the portions 104C of FIG. 1. In the embodiment of FIG. 4, the “leftmost” portions 104A and 104B may be in contact with one “top” portion 104C and one “bottom” portion 1040, forming a closed magnetic material loop in and around the solenoid 102; the “rightmost” portions 104A and 104B may do the same with the other “top” portion 104C and “bottom” portion 104C. Thus, the magnetic material 104 of FIG. 4 may be arranged in two spatially separated closed magnetic material loops in and around the solenoid 102. Similar structures may be used to arrange magnetic material in more than two spatially separated closed magnetic material loops in and around the solenoid (e.g., three loops or four loops, not shown).

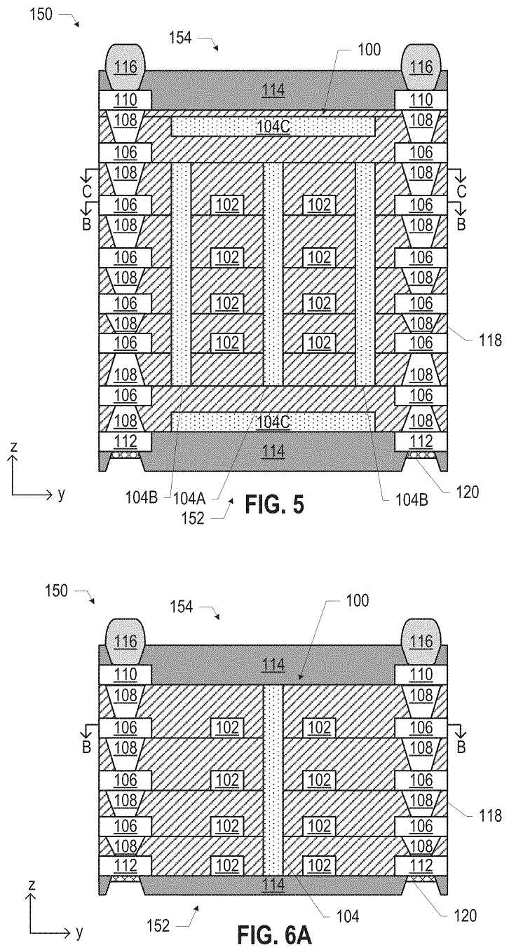

In the embodiments of FIGS. 1-4, the portions 104C of magnetic material are in contact with the portions 104A and 104B to form one or more closed loops of magnetic material. In other embodiments, the portions 104C may be spatially separated from the portions 104A and 104B. For example, FIG. 5 is a side, cross-sectional view of an IC package support 150 (sharing the perspective of the “A” sub-figures of FIGS. 1-4) in which the portions 104C of the magnetic material 104 are spaced away from the portions 104A and 104B by intervening dielectric material 118. The cross-sections through the sections B-B and C-C of FIG. 5 may take the form of any of the embodiments in the “A” and “B” sub-figures of FIGS. 1-4; more generally, any of the inductors 100 disclosed herein may include portions 104C of magnetic material that are spaced away from the portions 104A and 104B.

In the embodiments of FIGS. 1-5, the inductors 100 include portions 104C of magnetic material 104 between the solenoid 102 and the faces 152/154 of the IC package support 150. In some embodiments, an inductor 100 may substantially take the form of any of the embodiments of FIGS. 1-5, but may not include the portions 104C; instead, the inductor 100 may have magnetic material 104 that is located laterally interior and exterior to the solenoid 102, but not “above” or “below” the solenoid 102.

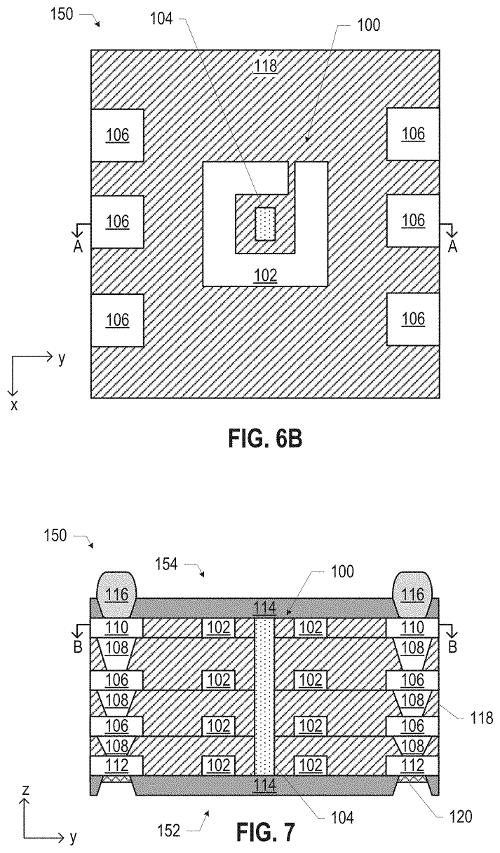

In some embodiments, an inductor 100 may include magnetic material 104 in an interior of the solenoid 102, but may not have magnetic material 104 exterior to the solenoid 102. For example, FIG. 6 illustrates an example IC package support 150 having many elements in common with the IC package supports 150 of FIGS. 1-3, but having a different arrangement of magnetic material 104 around the solenoid 102. Like FIG. 1, FIG. 6A is a side, cross-sectional view through the section A-A of FIG. 6B, and FIG. 6B is a top, cross-sectional view through the section B-B of FIG. 6A. In the embodiment of FIG. 6, the magnetic material 104 of the inductor 100 forms a single column in an interior of the solenoid 102, and no magnetic material 104 may be present exterior to the solenoid 102.

In the embodiments of FIGS. 1-5, the solenoid 102 is spaced apart from the solder resist material 114 at the faces 152 and 154 by intervening dielectric material 118. In other embodiments, the solenoid 102 may be adjacent to the solder resist material 114 at the first face 152 and/or adjacent to the solder resist material 114 at the second face 154. For example, FIG. 7 is a side, cross-sectional view of an IC package support 150 (sharing the perspective of the “A” sub-figures of FIGS. 1-4 and 6, and the perspective of FIG. 5) in which the solenoid 102 is in contact with the solder resist material 114 at the first face 152, and also in contact with the solder resist material 114 at the second face 154. The magnetic material 104 of the embodiment of FIG. 7 may also contact the solder resist material 114 at the faces 152/154. The embodiment of FIG. 7 illustrates magnetic material 104 solely in an interior of the solenoid 102, but in other embodiments (e.g., the embodiments of FIGS. 1-5, but in which the magnetic material portions 104C are absent), magnetic material 104 may be present interior and exterior to the solenoid 102 while the solenoid 102 is also in contact with the solder resist material 114 at one or both of the faces 152/154.

The IC package supports 150 illustrated in FIGS. 1-7 are coreless package supports in that they do not include a core of dielectric material (e.g., a glass prepreg material) with a set of layers of dielectric material and conductive pads/lines/vias built up on one side of the core and another set of layers of dielectric material and conductive pads/lines/vias built up on the other side of the core in an opposite orientation. The inductors 100 disclosed herein may also be included in cored package supports that do include such a core. Cored package supports may exhibit additional rigidity relative to coreless package supports (due to the presence of the core), but may have additional z-height relative to coreless package supports (due to the thickness of the core).

The IC package supports 150 disclosed herein may be manufactured using any suitable techniques. For example, FIGS. 8A-8O illustrate stages in an example process for manufacturing the IC package support 150 of FIG. 1; modifications to this process that may be made to fabricate others of the IC package supports 150 disclosed herein are discussed below. The cross-sectional views of FIGS. 8A-8O share a perspective with FIG. 1A.

FIG. 8A is a side, cross-sectional view of an assembly 200 including a panel 122 and a metal seed layer 121 on the panel 122. The panel 122 may be any suitably rigid and flat material on which subsequent manufacturing operations may be performed. In some embodiments, the panel 122 may include glass or a thick copper layer. The metal seed layer 121 may be a thin layer of a metal on which subsequent metal electrodeposition operations may be performed (e.g., a copper seed layer).

FIG. 8B is a side, cross-sectional view of an assembly 202 subsequent to forming conductive pads/lines 106 and one layer of the solenoid 102 on the assembly 200 (FIG. 8A). The conductive pads/lines 106 and the layer of the solenoid 102 may be formed by depositing a photoresist material, patterning the photoresist material to form openings in selective locations that expose the metal seed layer 121, performing an electrodeposition process (e.g., electroplating) to fill the openings with additional metal, and then removing the photoresist material.

FIG. 8C is a side, cross-sectional view of an assembly 204 subsequent to depositing a layer of dielectric material 118 on the assembly 202 (FIG. 8B) and then forming openings 124 in the layer of dielectric material 118 to selectively expose portions of the conductive pads/lines 106 and the layer of the solenoid 102. Although no openings 124 are shown in FIG. 8C as “landing” on the layer of the solenoid 102, such openings 124 are formed in cross-sections of the assembly 204 other than the cross-section shown in FIG. 8C as part of forming the solenoid 102. In some embodiments, the openings 124 may be formed by laser drilling (with the conductive pads/lines 106 and the layer of the solenoid 102 acting as laser stops) and may have a tapered shape that narrows towards the conductive pads/lines 106 and the layer of the solenoid 102. A desmear operation to clean the openings 124 may also be performed.

FIG. 8D is a side, cross-sectional view of an assembly 206 subsequent to forming conductive vias 108, additional conductive pads/lines 106, and an additional layer of the solenoid 102 on the assembly 204 (FIG. 8C). The conductive vias 108, additional conductive pads/lines 106, and the additional layer of the solenoid 102 may be formed by depositing a metal seed layer on the assembly 204, depositing a photoresist material (e.g., a dry film resist) on the metal seed layer, lithographically patterning the photoresist material to form openings that expose the metal seed layer, filling the openings with additional metal using an electrodeposition process, stripping away the photoresist material, and then performing a brief etch to remove the metal seed layer. The operations of FIGS. 8C and 8D describe a semi-additive patterning (SAP) process. Although FIG. 8D does not illustrate conductive vias in contact with the layers of the solenoid 102, such conductive vias would be present and part of the solenoid 102 in cross-sections other than the cross-section illustrated in FIG. 8D (e.g., to electrically connect different winding layers of the solenoid 102). As noted above, the dimensions of the conductive vias 108 and the thickness of the layers of dielectric material 118 may be selected to reduce stray capacitance in the inductor 100.

FIG. 8E is a side, cross-sectional view of an assembly 208 subsequent to forming additional layers of dielectric material 118, additional conductive vias 108, additional conductive pads/lines 106, and additional layers of the solenoid 102 on the assembly 206 (FIG. 8D) using multiple iterations of the SAP process discussed above with reference to FIGS. 8C and 8D. This SAP process may be repeated as desired to form a solenoid 102 (e.g., with a desired number of windings to achieve a desired Q value) and the other conductive structures of the assembly 208.

FIG. 8F is a side, cross-sectional view of an assembly 210 subsequent to forming vertical trenches 126 in the assembly 208 (FIG. 8E), and also forming a horizontal trench 128 in the assembly 208. The vertical trenches 126 may extend down to the metal seed layer 121, and may have the shape and arrangement of at least some of the portions 104A and 104B of the magnetic material 104 discussed above with reference to FIG. 1 (and as discussed further below). The horizontal trench 128 may extend partially into the topmost layer of dielectric material 118, but may not expose the solenoid 102 proximate to the top of the assembly 210, and may have the shape of one portion 104C of the magnetic material 104 discussed above with reference to FIG. 1 (and as discussed further below).

FIG. 8G is a side, cross-sectional view of an assembly 212 subsequent to filling the vertical trenches 126 and the horizontal trench 128 of the assembly 210 (FIG. 8F) with a magnetic material 104 to form most of the portions 104A and 104B, and one portion 104C. The magnetic material 104 may take the form of any of the embodiments disclosed herein. In some embodiments, filling the trenches 126/128 with the magnetic material 104 may be performed by plug pasting a magnetic composite paste into the trenches 126/128, followed by planarization to remove the excess magnetic composite paste, and then curing. In some embodiments, the magnetic composite paste may be stencil printed into the trenches 126/128; process parameters such as squeezing pressure, squeezing speed, viscosity of paste, curing temperature, and mask pattern accuracy may be varied to control the plugging morphology of the magnetic material 104 in the trenches 126/128. Printing accuracy with stencil printing may be improved by monitoring alignment with fiducials using a camera and compensating dynamically for any shrinkage or scaling. When manufacturing an IC package support 150 in which the top and/or bottom of the magnetic material 104 is coplanar with the top and/or bottom of the solenoid 102, respectively, (e.g., as discussed above with reference to FIG. 7), the solenoid 102 near the “top” and “bottom” of the magnetic material 104 may serve as a stop for planarization of the excess magnetic composite paste; damage to these portions of the solenoid 102 may result if the end of planarization is not triggered accurately. Embodiments in which the top and bottom of the magnetic material 104 is not coplanar with the top and bottom of the solenoid 102, respectively, may advantageously provide additional margin for this planarization without risking damage to the solenoid 102.

FIG. 8H is a side, cross-sectional view of an assembly 214 subsequent to depositing an additional layer of dielectric material 118, additional conductive vias 108, and conductive contacts 110 on the assembly 212 (FIG. 8G). The additional layer of dielectric material 118, additional conductive vias 108, and conductive contacts 110 may be formed using the SAP process discussed above with reference to FIGS. 8C and 8D. Although only a single additional layer of dielectric material 118 is shown in FIG. 8H, the SAP process of FIGS. 8C and 8D may be repeated as desired to form as many additional layers of dielectric material 118 and conductive structures as desired in the assembly 214. In embodiments in which the “top” portion 104C of the magnetic material 104 is to be spaced apart from the portions 104A and 104B (e.g., as discussed above with reference to FIG. 5), the horizontal trench 128 may not be formed in the assembly 210, and instead, a layer of dielectric material 118 may be deposited on the assembly 212, a horizontal trench may be formed in the layer of dielectric material 118, the trench may be filled with the magnetic material 104, and then the operations of FIG. 8H may be performed. In embodiments in which no “top” portion 104C of the magnetic material 104 is present, no corresponding horizontal trench may be formed.

FIG. 8I is a side, cross-sectional view of an assembly 216 subsequent to removing the panel 122 of the assembly 214 (FIG. 8H), performing a seed etch to remove the metal seed layer 121, and depositing a layer of dielectric material 118 at the “bottom” of the assembly 216.

FIG. 8J is a side, cross-sectional view of an assembly 218 subsequent to forming vertical trenches 130 in the assembly 216 (FIG. 8I), and also forming a horizontal trench 132 in the assembly 216. The vertical trenches 130 may extend down to meet the magnetic material 104 in the assembly 216, and may have the shape and arrangement of at least some of the portions 104A and 104B of the magnetic material 104 discussed above with reference to FIG. 1 (and as discussed further below). The horizontal trench 132 may extend partially into the bottommost layer of dielectric material 118, but may not expose the solenoid 102 proximate to the bottom of the assembly 218, and may have the shape of the other portion 104C of the magnetic material 104 discussed above with reference to FIG. 1 (and as discussed further below).

FIG. 8K is a side, cross-sectional view of an assembly 220 subsequent to filling the vertical trenches 130 and the horizontal trench 132 of the assembly 218 (FIG. 8J) with a magnetic material 104 to complete the portions 104A and 104B, and form the other portion 104C. Any of the techniques discussed above with reference to FIG. 8G may be used to provide the additional magnetic material of the assembly 220. The assembly 220 includes a complete inductor 100. In embodiments in which the “bottom” portion 104C of the magnetic material 104 is to be spaced apart from the portions 104A and 104B (e.g., as discussed above with reference to FIG. 5), the horizontal trench 132 may not be formed in the assembly 218, and instead, a layer of dielectric material 118 may be deposited on the assembly 220, a horizontal trench may then be formed in the layer of dielectric material 118, and the trench may be filled with the magnetic material 104. In embodiments in which no “bottom” portion 104C of the magnetic material 104 is present, no corresponding horizontal trench may be formed.

FIG. 8L is a side, cross-sectional view of an assembly 222 subsequent to depositing a layer of dielectric material 118 on the bottom of the assembly 220 (FIG. 8K) and then forming openings 134 in the layer of dielectric material 118 to selectively expose portions of the conductive pads/lines 106. The formation of the openings 134 may take the form of any of the embodiments of the formation of the openings 124 discussed above. For example, the openings 134 may have a tapered shape that narrows towards the conductive pads/lines 106 (with an opposite orientation as the openings 124). A desmear operation to clean the openings 134 may also be performed. Although only a single additional layer of dielectric material 118 is shown in FIG. 8L, the SAP process of FIGS. 8C and 8D may be repeated as desired to form as many additional layers of dielectric material 118 and conductive structures as desired in the assembly 222 before formation of the openings 134.

FIG. 8M is a side, cross-sectional view of an assembly 224 subsequent to forming conductive vias 108 and conductive contacts 112 on the assembly 222 (FIG. 8L). The conductive vias 108 and conductive contacts 112 may be formed using the operations discussed above with reference to FIG. 8D (and thus the operations of FIGS. 8L and 8M may be an SAP process).

FIG. 8N is a side, cross-sectional view of an assembly 226 subsequent to depositing layers of solder resist material 114 on both faces of the assembly 224 (FIG. 8M), and forming openings 136 and 138 in the solder resist material 114 (e.g., by photolithography). The openings 136 and 138 may expose the conductive contacts 110 and 112, respectively, and may taper towards the conductive contacts 110 and 112, respectively.

FIG. 8O is a side, cross-sectional view of an assembly 228 subsequent to forming solder balls 116 in the openings 136 of the assembly 226 (FIG. 8N), and providing a surface finish material 120 on the exposed portions of the conductive contacts 112 in the openings 138. The resulting assembly 228 may take the form of the IC package support 150 of FIG. 1.

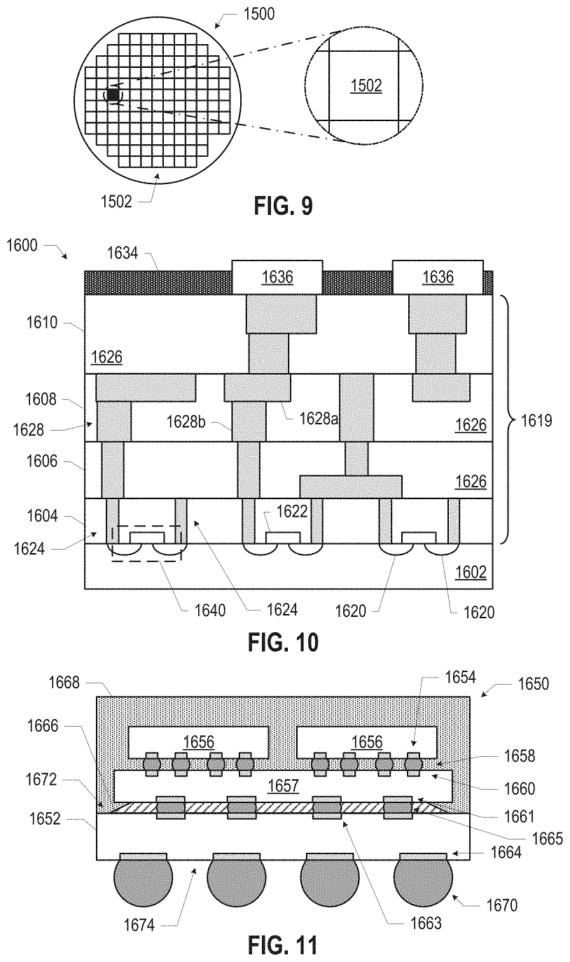

The inductors 100 and IC package supports 150 disclosed herein may include, or be included in, any suitable electronic component. FIGS. 9-13 illustrate various examples of apparatuses that may include any of the inductors 100 or IC package supports 150 disclosed herein, or may be included in an IC package that also includes any of the inductors 100 or IC package supports 150 disclosed herein.

FIG. 9 is a top view of a wafer 1500 and dies 1502 that may be included in an IC package including one or more inductors 100 or IC package supports 150 (e.g., as discussed below with reference to FIG. 11) in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., some of the transistors 1640 of FIG. 10, discussed below) and/or supporting circuitry to route electrical signals to the transistors, as well as any other IC components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 13) or other logic that is configured to store information in the memory devices or execute instructions stored in the memory array.

FIG. 10 is a side, cross-sectional view of an IC device 1600 that may be included in an IC package including one or more inductors 100 or IC package supports 150 (e.g., as discussed below with reference to FIG. 11), in accordance with any of the embodiments disclosed herein. One or more of the IC devices 1600 may be included in one or more dies 1502 (FIG. 9). The IC device 1600 may be formed on a substrate 1602 (e.g., the wafer 1500 of FIG. 9) and may be included in a die (e.g., the die 1502 of FIG. 9). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 9) or a wafer (e.g., the wafer 1500 of FIG. 9).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 10 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or all-around gate transistors, such as nanoribbon and nanowire transistors.

Each transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 10 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 10). Although a particular number of interconnect layers 1606-1610 is depicted in FIG. 10, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 10. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 10. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 10, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

FIG. 11 is a side, cross-sectional view of an example IC package 1650 that may include one or more inductors 100 in an IC package support 150. For example, the package substrate 1652 or the interposer 1657 (discussed further below) may be an IC package support 150 and may include one or more inductors 100 in accordance with any of the embodiments disclosed herein. In some embodiments, the IC package 1650 may be a system-in-package (SiP).

The package substrate 1652 may be formed of a dielectric material (e.g., a ceramic, a dielectric buildup film, an epoxy film having filler particles therein, etc.), and may have conductive pathways extending through the dielectric material between the face 1672 and the face 1674, or between different locations on the face 1672, and/or between different locations on the face 1674. These conductive pathways may take the form of any of the interconnects 1628 discussed above with reference to FIG. 10. In some embodiments, the package substrate 1652 may include one or more inductors 100 in accordance with any of the embodiments disclosed herein. In some embodiments, no inductors 100 may be included in the package substrate 1652.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 or to the inductors 100 (or to other devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 11 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665.

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 11 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

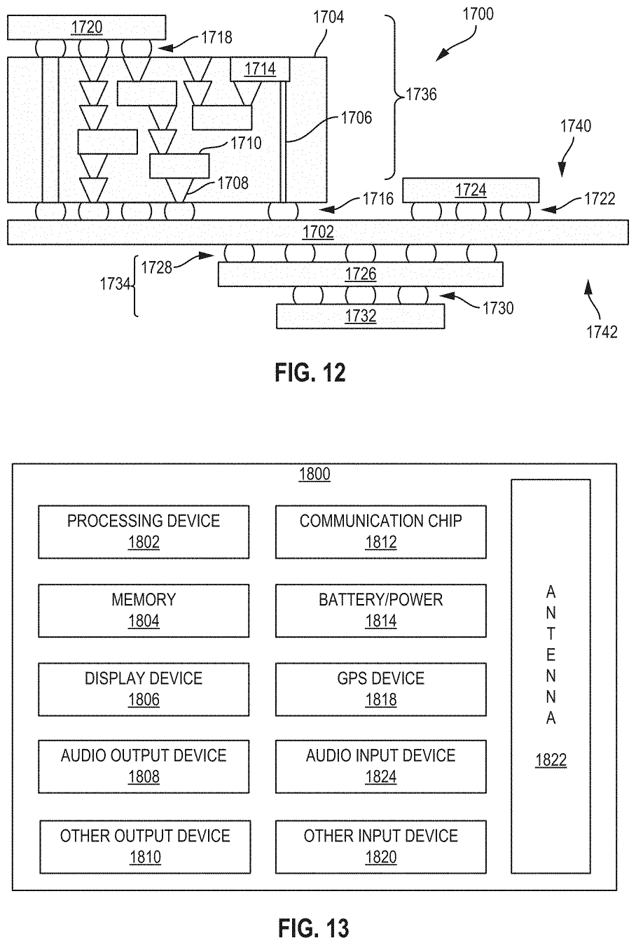

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 11 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 12.

In some embodiments, the interposer 1657 may include one or more inductors 100 in accordance with any of the embodiments disclosed herein. In some embodiments, no inductors 100 may be included in the package substrate 1652. The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high bandwidth memory).

Although the IC package 1650 illustrated in FIG. 11 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 11, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 12 is a side, cross-sectional view of an IC device assembly 1700 that may include one or more IC packages including one or more of the inductors 100 and/or IC package supports 150 disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 11 (e.g., may include one or more inductors 100 in an IC package support 150).

In some embodiments, the circuit board 1702 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 12 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 12), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 12, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 9), an IC device (e.g., the IC device 1600 of FIG. 10), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 12, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art. In some embodiments, the package interposer 1704 may include one or more inductors 100.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 12 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 13 is a block diagram of an example electrical device 1800 that may include one or more IC package supports 150 including one more inductors 100 in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 13 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 13, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random access memory (eDRAM) or spin transfer torque magnetic random access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 is an integrated circuit (IC) package support including an inductor, wherein the inductor includes a solenoid, a first portion of a magnetic material in an interior of the solenoid, and a second portion of magnetic material outside the interior of the solenoid.

Example 2 includes the subject matter of Example 1, and further specifies that the solenoid includes a plurality of conductive lines and conductive vias through multiple layers of dielectric material.

Example 3 includes the subject matter of any of Examples 1-2, and further specifies that the solenoid has a height that is less than 500 microns.

Example 4 includes the subject matter of any of Examples 1-3, and further specifies that the first portion of the magnetic material is oriented along a longitudinal axis of the solenoid.

Example 5 includes the subject matter of any of Examples 1-4, and further specifies that the first portion of the magnetic material has a height that is greater than a height of the solenoid.

Example 6 includes the subject matter of any of Examples 1-5, and further specifies that the solenoid includes copper.

Example 7 includes the subject matter of any of Examples 1-6, and further specifies that the second portion of the magnetic material is oriented parallel to a longitudinal axis of the solenoid.

Example 8 includes the subject matter of Example 7, and further specifies that the second portion of the magnetic material has a cylinder shape.

Example 9 includes the subject matter of Example 7, and further specifies that the second portion of the magnetic material has a planar shape.

Example 10 includes the subject matter of Example 7, and further specifies that the second portion of the magnetic material has a C-shaped cross-section.

Example 11 includes the subject matter of any of Examples 8-10, and further specifies that the inductor further includes a third portion of the magnetic material outside the interior of the solenoid, and the third portion of the magnetic material is oriented perpendicular to a longitudinal axis of the solenoid.

Example 12 includes the subject matter of Example 11, and further specifies that the third portion of the magnetic material is in contact with the first portion of the magnetic material and the second portion of the magnetic material.

Example 13 includes the subject matter of Example 11, and further specifies that the third portion of the magnetic material is spaced apart from the first portion of the magnetic material by a dielectric material, and the third portion of the magnetic material is spaced apart from the second portion of the magnetic material by a dielectric material.

Example 14 includes the subject matter of any of Examples 1-13, and further specifies that the first portion of the magnetic material in the interior of the solenoid is one of a plurality of first portions of the magnetic material in the interior of the solenoid, and different ones of the first portions of the magnetic material are spaced apart from each other by a dielectric material.

Example 15 includes the subject matter of any of Examples 1-14, and further specifies that the second portion of the magnetic material outside the interior of the solenoid is one of a plurality of second portions of the magnetic material outside the interior of the solenoid, and different ones of the second portions of the magnetic material are spaced apart from each other by a dielectric material.

Example 16 includes the subject matter of any of Examples 1-15, and further specifies that the first portion of the magnetic material and the second portion of the magnetic material are part of magnetic material loop that is partially disposed in the interior of the solenoid and partially disposed outside the interior of the solenoid.

Example 17 includes the subject matter of any of Examples 1-16, and further specifies that the inductor is spaced apart from solder resist at a face of the IC package support.

Example 18 includes the subject matter of any of Examples 1-17, and further specifies that the inductor is in contact with solder resist at a face of the IC package support.

Example 19 includes the subject matter of any of Examples 1-18, and further specifies that the IC package support is coreless.

Example 20 includes the subject matter of any of Examples 1-19, and further specifies that the IC package support includes a buildup film.

Example 21 includes the subject matter of any of Examples 1-20, and further specifies that the magnetic material includes a magnetic paste.

Example 22 includes the subject matter of any of Examples 1-21, and further specifies that the magnetic material includes iron, cobalt, or nickel.

Example 23 includes the subject matter of any of Examples 1-22, and further specifies that the magnetic material includes an epoxy resin.

Example 24 includes the subject matter of any of Examples 1-23, and further specifies that the IC package support is a package substrate or an interposer.

Example 25 is an integrated circuit (IC) package, including an IC package support having an inductor embedded therein, wherein the inductor includes a solenoid and a magnetic structure around the solenoid, and the magnetic structure includes multiple portions of magnetic material oriented perpendicular to a longitudinal axis of the solenoid; and a die coupled to the IC package support.

Example 26 includes the subject matter of Example 25, and further specifies that the solenoid includes a plurality of conductive lines and conductive vias through multiple layers of dielectric material.

Example 27 includes the subject matter of any of Examples 25-26, and further specifies that the solenoid has a height that is less than 500 microns.

Example 28 includes the subject matter of any of Examples 25-27, and further specifies that the solenoid includes copper.

Example 29 includes the subject matter of any of Examples 25-28, and further specifies that a first portion of the magnetic material is in an interior of the solenoid.

Example 30 includes the subject matter of Example 29, and further specifies that the first portion of the magnetic material has a height that is greater than a height of the solenoid.

Example 31 includes the subject matter of any of Examples 29-30, and further specifies that a second portion of the magnetic material is outside an interior of the solenoid.

Example 32 includes the subject matter of Example 31, and further specifies that the second portion of the magnetic material has a cylinder shape.

Example 33 includes the subject matter of Example 31, and further specifies that the second portion of the magnetic material has a planar shape.

Example 34 includes the subject matter of Example 31, and further specifies that the second portion of the magnetic material has a C-shaped cross-section.

Example 35 includes the subject matter of any of Examples 31-34, and further specifies that the inductor further includes a third portion of the magnetic material, and the third portion of the magnetic material is oriented perpendicular to a longitudinal axis of the solenoid.

Example 36 includes the subject matter of Example 35, and further specifies that the third portion of the magnetic material is outside the interior of the solenoid.

Example 37 includes the subject matter of any of Examples 35-36, and further specifies that the third portion of the magnetic material is in contact with the first portion of the magnetic material and the second portion of the magnetic material.

Example 38 includes the subject matter of any of Examples 35-36, and further specifies that the third portion of the magnetic material is spaced apart from the first portion of the magnetic material by a dielectric material, and the third portion of the magnetic material is spaced apart from the second portion of the magnetic material by a dielectric material.

Example 39 includes the subject matter of any of Examples 31-38, and further specifies that the first portion of the magnetic material in the interior of the solenoid is one of a plurality of first portions of the magnetic material in the interior of the solenoid, and different ones of the first portions of the magnetic material are spaced apart from each other by a dielectric material.

Example 40 includes the subject matter of any of Examples 31-39, and further specifies that the second portion of the magnetic material outside the interior of the solenoid is one of a plurality of second portions of the magnetic material outside the interior of the solenoid, and different ones of the second portions of the magnetic material are spaced apart from each other by a dielectric material.

Example 41 includes the subject matter of any of Examples 31-40, and further specifies that the first portion of the magnetic material and the second portion of the magnetic material are part of magnetic material loop that is partially disposed in the interior of the solenoid and partially disposed outside the interior of the solenoid.

Example 42 includes the subject matter of any of Examples 25-41, and further specifies that the inductor is spaced apart from solder resist at a face of the IC package support.

Example 43 includes the subject matter of any of Examples 25-42, and further specifies that the inductor is in contact with solder resist at a face of the IC package support.

Example 44 includes the subject matter of any of Examples 25-43, and further specifies that the IC package support is coreless.

Example 45 includes the subject matter of any of Examples 25-44, and further specifies that the IC package support includes a buildup film.

Example 46 includes the subject matter of any of Examples 25-45, and further specifies that the magnetic material includes a magnetic paste.

Example 47 includes the subject matter of any of Examples 25-46, and further specifies that the magnetic material includes iron, cobalt, or nickel.

Example 48 includes the subject matter of any of Examples 25-47, and further specifies that the magnetic material includes an epoxy resin.

Example 49 includes the subject matter of any of Examples 25-48, and further specifies that the IC package support is a package substrate or an interposer.

Example 50 includes the subject matter of any of Examples 25-49, and further specifies that the die includes wireless communication circuitry.

Example 51 is a coreless integrated circuit (IC) package support, including an inductor, wherein the inductor includes a solenoid, and a magnetic material in an interior of the solenoid.

Example 52 includes the subject matter of Example 51, and further specifies that the solenoid includes a plurality of conductive lines and conductive vias through multiple layers of dielectric material.

Example 53 includes the subject matter of any of Examples 51-52, and further specifies that the solenoid has a height that is less than 500 microns.

Example 54 includes the subject matter of any of Examples 51-53, and further specifies that the magnetic material is oriented along a longitudinal axis of the solenoid.

Example 55 includes the subject matter of any of Examples 51-54, and further specifies that the magnetic material has a height that is greater than a height of the solenoid.

Example 56 includes the subject matter of any of Examples 51-55, and further specifies that the solenoid includes copper.

Example 57 includes the subject matter of any of Examples 51-56, and further specifies that the magnetic material in the interior of the solenoid is a first portion of magnetic material, and the inductor further includes a second portion of magnetic material outside the interior of the solenoid.

Example 58 includes the subject matter of Example 57, and further specifies that the second portion of the magnetic material is oriented parallel to a longitudinal axis of the solenoid.

Example 59 includes the subject matter of any of Examples 57-58, and further specifies that the second portion of the magnetic material has a cylinder shape.

Example 60 includes the subject matter of any of Examples 57-58, and further specifies that the second portion of the magnetic material has a planar shape.

Example 61 includes the subject matter of any of Examples 57-58, and further specifies that the second portion of the magnetic material has a C-shaped cross-section.

Example 62 includes the subject matter of any of Examples 57-61, and further specifies that the inductor further includes a third portion of the magnetic material outside the interior of the solenoid, and the third portion of the magnetic material is oriented perpendicular to a longitudinal axis of the solenoid.

Example 63 includes the subject matter of Example 62, and further specifies that the third portion of the magnetic material is in contact with the first portion of the magnetic material and the second portion of the magnetic material.

Example 64 includes the subject matter of Example 62, and further specifies that the third portion of the magnetic material is spaced apart from the first portion of the magnetic material by a dielectric material, and the third portion of the magnetic material is spaced apart from the second portion of the magnetic material by a dielectric material.

Example 65 includes the subject matter of any of Examples 57-64, and further specifies that the first portion of the magnetic material in the interior of the solenoid is one of a plurality of first portions of the magnetic material in the interior of the solenoid, and different ones of the first portions of the magnetic material are spaced apart from each other by a dielectric material.

Example 66 includes the subject matter of any of Examples 57-65, and further specifies that the second portion of the magnetic material outside the interior of the solenoid is one of a plurality of second portions of the magnetic material outside the interior of the solenoid, and different ones of the second portions of the magnetic material are spaced apart from each other by a dielectric material.

Example 67 includes the subject matter of any of Examples 57-66, and further specifies that the first portion of the magnetic material and the second portion of the magnetic material are part of magnetic material loop that is partially disposed in the interior of the solenoid and partially disposed outside the interior of the solenoid.

Example 68 includes the subject matter of any of Examples 51-67, and further specifies that the inductor is spaced apart from solder resist at a face of the IC package support.

Example 69 includes the subject matter of any of Examples 51-68, and further specifies that the inductor is in contact with solder resist at a face of the IC package support.

Example 70 includes the subject matter of any of Examples 51-69, and further specifies that the IC package support includes a buildup film.

Example 71 includes the subject matter of any of Examples 51-70, and further specifies that the magnetic material includes a magnetic paste.

Example 72 includes the subject matter of any of Examples 51-71, and further specifies that the magnetic material includes iron, cobalt, or nickel.

Example 73 includes the subject matter of any of Examples 51-72, and further specifies that the magnetic material includes an epoxy resin.

Example 74 includes the subject matter of any of Examples 51-73, and further specifies that the IC package support is a package substrate or an interposer.

Example 75 is a computing device, including: a circuit board; and an integrated circuit (IC) package coupled to the circuit board, wherein the IC package includes an IC package support and a computing component coupled to the IC package support, the IC package support includes an inductor, and the inductor includes a solenoid having magnetic material interior to the solenoid or exterior to the solenoid.

Example 76 includes the subject matter of Example 75, and further specifies that the magnetic material includes portions parallel to a longitudinal axis of the solenoid.

Example 77 includes the subject matter of Example 76, and further specifies that the magnetic material includes portions perpendicular to the longitudinal axis of the solenoid.

Example 78 includes the subject matter of Example 77, and further specifies that a portion perpendicular to the longitudinal axis of the solenoid is in contact with a portion parallel to the longitudinal axis of the solenoid.

Example 79 includes the subject matter of any of Examples 75-78, and further specifies that the magnetic material forms at least one loop through and around the solenoid.

Example 80 includes the subject matter of any of Examples 75-78, and further specifies that the magnetic material forms multiple loops through and around the solenoid.

Example 81 includes the subject matter of any of Examples 75-80, and further specifies that the computing component includes a die.

Example 82 includes the subject matter of any of Examples 75-81, and further specifies that the circuit board is a motherboard.

Example 83 includes the subject matter of any of Examples 75-82, and further includes: an antenna communicatively coupled to the circuit board.

Example 84 includes the subject matter of any of Examples 75-83, and further includes: a display device communicatively coupled to the circuit board.

Example 85 includes the subject matter of any of Examples 75-84, and further specifies that the computing device is a handheld computing device or a server computing device.

Example 86 includes the subject matter of any of Examples 75-85, and further specifies that the inductor includes magnetic material interior to the solenoid and exterior to the solenoid.

Example 87 includes the subject matter of any of Examples 75-85, and further specifies that the inductor includes magnetic material exterior to the solenoid but not interior to the solenoid.

1. An integrated circuit (IC) package support, comprising:
an inductor, including:
a solenoid,
a first portion of a magnetic material in an interior of the solenoid, and
a second portion of magnetic material outside the interior of the solenoid.

2. The IC package support of claim 1, wherein the solenoid includes a plurality of conductive lines and conductive vias through multiple layers of dielectric material.

3. The IC package support of claim 1, wherein the first portion of the magnetic material is oriented along a longitudinal axis of the solenoid.

4. The IC package support of claim 1, wherein the first portion of the magnetic material has a height that is greater than a height of the solenoid.

5. The IC package support of claim 1, wherein the second portion of the magnetic material is oriented parallel to a longitudinal axis of the solenoid.

6. The IC package support of claim 5, wherein the second portion of the magnetic material has a cylinder shape, a planar shape, or a C-shaped cross-section.

7. The IC package support of claim 1, wherein the IC package support is coreless.

8. The IC package support of claim 1, wherein the magnetic material includes a magnetic paste.

9. The IC package support of claim 1, wherein the IC package support is a package substrate or an interposer.

10. An integrated circuit (IC) package, comprising:
an IC package support having an inductor embedded therein, wherein the inductor includes a solenoid and a magnetic structure around the solenoid, and the magnetic structure includes multiple portions of magnetic material oriented perpendicular to a longitudinal axis of the solenoid; and
a die coupled to the IC package support.

11. The IC package support of claim 10, wherein a first portion of the magnetic material is in an interior of the solenoid and a second portion of the magnetic material is outside an interior of the solenoid.

12. The IC package of claim 11, wherein the inductor further includes a third portion of the magnetic material, and the third portion of the magnetic material is oriented perpendicular to a longitudinal axis of the solenoid.

13. The IC package of claim 12, wherein the third portion of the magnetic material is in contact with the first portion of the magnetic material and the second portion of the magnetic material.

14. The IC package of claim 12, wherein the third portion of the magnetic material is spaced apart from the first portion of the magnetic material by a dielectric material, and the third portion of the magnetic material is spaced apart from the second portion of the magnetic material by a dielectric material.

15. A coreless integrated circuit (IC) package support, comprising:
an inductor, including:
a solenoid, and
a magnetic material in an interior of the solenoid.

16. The IC package support of claim 15, wherein the magnetic material in the interior of the solenoid is a first portion of magnetic material, and the inductor further includes a second portion of magnetic material outside the interior of the solenoid.

17. The IC package support of claim 15, wherein the inductor is spaced apart from solder resist at a face of the IC package support.

18. The IC package support of claim 15, wherein the inductor is in contact with solder resist at a face of the IC package support.

19. The IC package support of claim 15, wherein the magnetic material includes an epoxy resin.

20. A computing device, comprising:
a circuit board; and
an integrated circuit (IC) package coupled to the circuit board, wherein the IC package includes an IC package support and a computing component coupled to the IC package support, the IC package support includes an inductor, and the inductor includes a solenoid having magnetic material interior to the solenoid or exterior to the solenoid.

21. The computing device of claim 20, wherein the magnetic material includes portions parallel to a longitudinal axis of the solenoid.

22. The computing device of claim 21, wherein the magnetic material includes portions perpendicular to the longitudinal axis of the solenoid.

23. The computing device of claim 20, wherein the circuit board is a motherboard.

24. The computing device of claim 20, wherein the computing device is a handheld computing device or a server computing device.

25. The computing device of claim 20, wherein the inductor includes magnetic material interior to the solenoid and exterior to the solenoid.
